(19) United States
(12) Patent Application Publication
(10) Pub. No.: US 2025/0189876 A1
(43) Pub. Date: Jun. 12, 2025

(54) THERMAL MODULE AND PROJECTOR

(71) Applicant: Coretronic Corporation, Hsin-Chu (TW)

(72) Inventors: Pei-Rong Wu, Hsin-Chu (TW); Shi-Wen Lin, Hsin-Chu (TW)

(73) Assignee: Coretronic Corporation, Hsin-Chu (TW)

(21) Appl. No.: 18/954,505

(22) Filed: Nov. 20, 2024

(30) Foreign Application Priority Data
Dec. 12, 2023 (CN) 202311701491.8

(51) Int. Cl. G03B 21/16; H05K 7/20

(52) U.S. Cl. CPC G03B 21/16; H05K 7/20154; H05K 7/2039

(57) ABSTRACT

A thermal module including a heat sink and a projector are provided. The heat sink includes a body and heat sink fins. The body includes a fixed plate and partition plates. The fixed plate has a first surface, a second surface and a third surface. The first surface is opposite to the second surface, and the third surface is connected to the first and second surfaces. Spaces form between the partition plates, and the heat sink fin is disposed correspondingly in each space. Each heat sink fin has a corrugated structure with multiple segments, and a fractured structure is provided on the surface of each segment. The third surface and the side surface connected to the end surfaces of the partition plates form an air guide surface, and the heat sink receives or discharges air flow with the air guide surface.

### CROSS-REFERENCE TO RELATED APPLICATION

This application claims the priority benefit of China application serial no. 202311701491.8, filed on Dec. 12, 2023. The entirety of the above-mentioned patent application is hereby incorporated by reference herein and made a part of this specification.

### BACKGROUND

### Technical Field

The disclosure relates to a thermal module and a projector.

### Description of Related Art

The main design concerns of mainstream projector products are the volume, price, and noise of the heat sink. There are many manufacturing methods for manufacturing heat dissipation fins. The most common, simple and cheap method is aluminum extrusion. It is also the most commonly used manufacturing method for pure aluminum heat sinks without heat pipes currently on the market.

In addition, heat sinks may also be manufactured by forging or die casting. The degree of freedom of fin shape and arrangement of the heat sink manufactured by forging is much higher than that of aluminum extrusion. In addition, fins using the stacked fin process have higher fin density.

The heat sinks used in current solid-state light source projectors usually adopt forced cooling with fans and heat dissipation fins, and the fin structures mostly adopt flat fins. With the evolution of products and the increasing demand from users for high-brightness and low-noise products, the heat generated by high-brightness products generally increases. Therefore, without increasing noise, the temperature must be reduced by increasing the volume of the heat sink.

However, as the volume of the heat sink increases, the product becomes more cumbersome, less portable, and poses greater risks during installation, leading to user inconvenience.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the disclosure was acknowledged by a person of ordinary skill in the art.

### SUMMARY

A thermal module adapted for dissipating heat from a heat source is provided in an embodiment of the disclosure. The thermal module includes a heat sink adapted for receiving or discharging air flow. The heat sink includes a body and multiple heat sink fins. The body includes a fixed plate and multiple partition plates. The fixed plate has a first surface, a second surface, and a third surface. The first surface is opposite to the second surface, and the third surface is connected to the first surface and the second surface. The heat source is adapted to be disposed closer to the first surface of the fixed plate than to the second surface of the fixed plate. The second surface of the fixed plate is parallel to a first direction. A number of the partition plates is more than three and the partition plates are respectively parallel to a second direction and connected to the second surface of the fixed plate by end surfaces. The first direction is perpendicular to the second direction. Multiple spaces are formed between the partition plates and the second surface of the fixed plate. The heat sink fins are respectively disposed in the spaces. Each of the heat sink fins has a corrugated structure, and an orthographic projection of the corrugated structure on a plane formed by the first direction and the second direction is corrugated. The corrugated structure has multiple segments. Each of the segments is provided with a fractured structure on a surface extending in a third direction. The third direction is perpendicular to the first direction and the second direction. The third surface of the fixed plate and a side surface connected to the end surfaces of the partition plates form an air guide surface, and the heat sink receives or discharges the air flow through the air guide surface.

A projector including a lighting module, a light valve module, a lens module, and a thermal module is provided in an embodiment of the disclosure. The lighting module is configured to provide an illumination beam. The light valve module is disposed on a transmission path of the illumination beam to convert the illumination beam into an image beam. The lens module is disposed on a transmission path of the image beam to project the image beam. The thermal module is configured to dissipate heat from a heat source. The heat source includes at least one of the lighting module and the light valve module. The thermal module includes a heat sink adapted for receiving or discharging an air flow. The heat sink includes a body and multiple heat sink fins. The body includes a fixed plate and multiple partition plates. The fixed plate has a first surface, a second surface, and a third surface. The first surface is opposite to the second surface, and the third surface is connected to the first surface and the second surface. The heat source is disposed closer to the first surface of the fixed plate than to the second surface of the fixed plate. The second surface of the fixed plate is parallel to a first direction. A number of the partition plates is more than three and the partition plates are respectively parallel to a second direction and connected to the second surface of the fixed plate by end surfaces. The first direction is perpendicular to the second direction. Multiple spaces are formed between the partition plates and the second surface of the fixed plate. The heat sink fins are respectively disposed in the multiple spaces. Each of the heat sink fins has a corrugated structure, and an orthographic projection of the corrugated structure on a plane formed by the first direction and the second direction is corrugated. The corrugated structure has multiple segments. Each of the segments is provided with a fractured structure on a surface extending in a third direction. The third direction is perpendicular to the first direction and the second direction. The third surface of the fixed plate and a side surface connected to the end surfaces of the partition plates form an air guide surface, and the heat sink receives or discharges the air flow through the air guide surface.

Other objectives, features and advantages of the disclosure will be further understood from the further technological features disclosed by the embodiments of the disclosure wherein there are shown and described preferred embodiments of this disclosure, simply by way of illustration of modes best suited to carry out the disclosure.

### BRIEF DESCRIPTION OF THE DRAWINGS

FIG. 1 is a schematic diagram of a projector of an embodiment of the disclosure.

FIG. 2 is a schematic diagram of the thermal module in FIG. 1.

FIG. 3 is a schematic diagram of the heat sink of FIG. 2.

FIG. 4A is a three-dimensional schematic diagram of the heat sink fin.

FIG. 4B is a cross-sectional schematic diagram of the heat sink.

FIG. 5A is a schematic diagram of a triangular fractured structure.

FIG. 5B is a schematic diagram of the fractured structure being a concave-convex structure.

### DETAILED DESCRIPTION OF DISCLOSED EMBODIMENTS

In the following detailed description of the preferred embodiments, reference is made to the accompanying drawings which form a part hereof, and in which are shown by way of illustration specific embodiments in which the disclosure may be practiced. In this regard, directional terminology, such as “top,” “bottom,” “front,” “back,” etc., is used with reference to the orientation of the Figure(s) being described. The components of the disclosure may be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the disclosure. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

The above and other technical contents, features and effects of the disclosure will be clear from the below detailed description of an embodiment of the disclosure with reference to accompanying drawings. The directional terms mentioned in the embodiments below, like “above”, “below”, “left”, “right”, “front”, and “back”, refer to the directions in the appended drawings. Therefore, the directional terms are used to illustrate rather than limit the disclosure. In addition, the term “connected” mentioned in the following embodiments includes the meanings of “direct connection” and “indirect connection”.

A thermal module and a projector that have good heat dissipation effect and are light and thin in overall volume are provided in the disclosure. The other objectives and advantages of the disclosure may be further understood from the descriptive features disclosed in the disclosure.

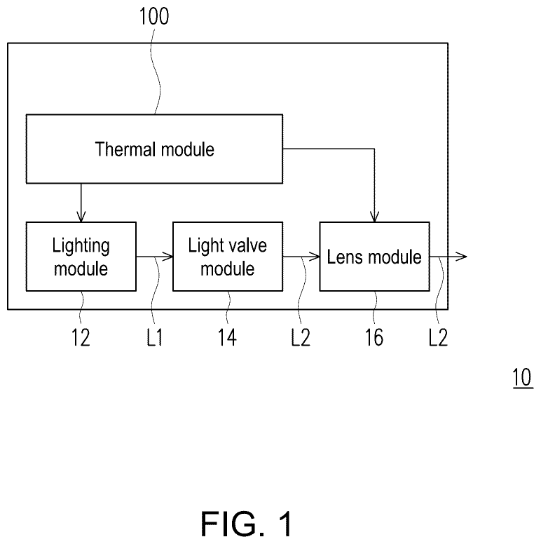

FIG. 1 is a schematic diagram of a projector of an embodiment of the disclosure. Referring to FIG. 1, the projector 10 includes a lighting module 12, a light valve module 14, a lens module 16, and a thermal module 100.

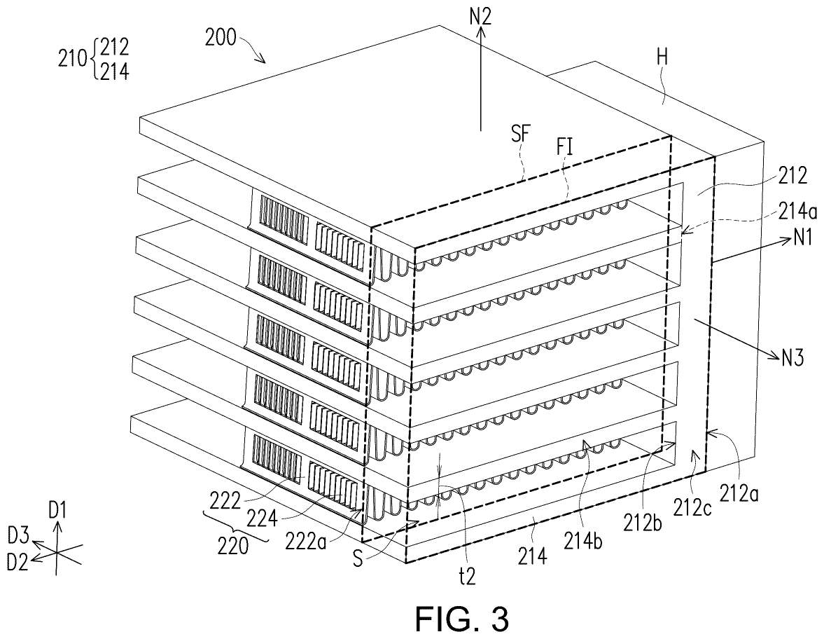

The above-mentioned lighting module 12 is configured to provide the illumination beam L1, and the light valve module 14 is disposed on the transmission path of the illumination beam L1 to convert the illumination beam L1 into the image beam L2. The lens module 16 is disposed on the transmission path of the image beam L2 to project the image beam L2 out of the projector 10. The thermal module 100 is configured to dissipate heat from the heat source H (shown in FIG. 3). The heat source H may be at least one of the lighting module 12 and the light valve module 14. The heat source H may also be a heat-generating element in the lighting module 12 or/and a heat-generating element in the light valve module 14.

The above-mentioned light source module 12 configured to provide the illumination beam L1 includes a light source. The light source module 12 may also include optical elements such as wavelength conversion elements, light homogenizing elements, filter elements, light guide elements, light transmission elements, etc. The light source module 12 is configured to provide light beams of different wavelengths as sources of the illumination beam. The light source may be a solid-state light source, such as light-emitting diodes (LEDs), laser diodes (LDs), or a combination thereof. The light valve module 14 includes a light valve. The light valve is, for example, a reflective optical modulator such as a liquid crystal on silicon panel (LCoS panel) and a digital micro-mirror device (DMD). In some embodiments, the light valve may also be a transmissive optical modulator, such as a transparent liquid crystal panel, an electro-optical modulator, a magneto-optical modulator, or an acousto-optic modulator (AOM), etc. In addition, the lens module 16, for example, includes a combination of one or more optical lenses with diopter. Optical lenses include, for example, various combinations of non-planar lenses such as biconcave lenses, biconvex lenses, concave-convex lenses, convex-concave lenses, plano-convex lenses, and plano-concave lenses. The disclosure does not limit the form and type of the lens module 16.

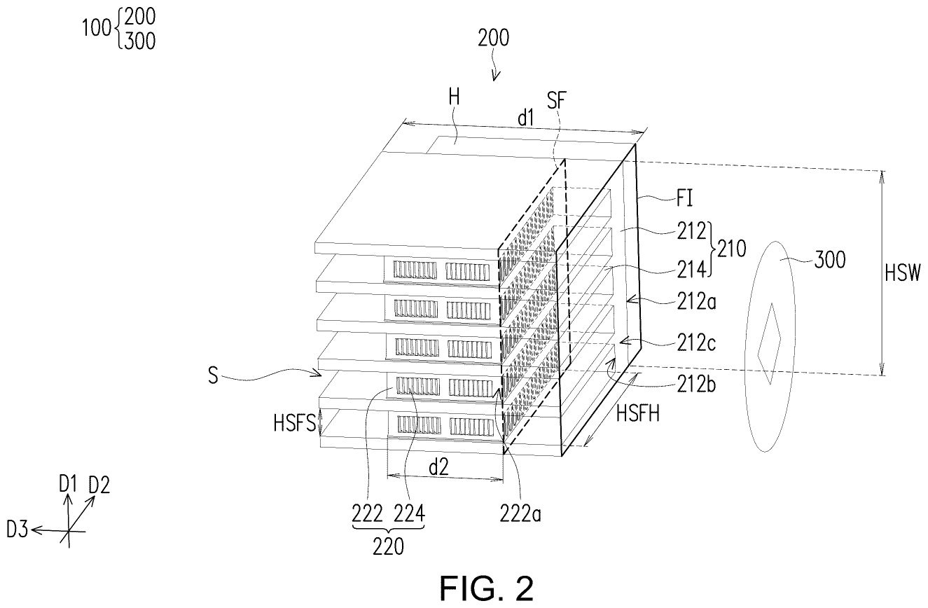

FIG. 2 is a schematic diagram of the thermal module in FIG. 1, and FIG. 3 is a schematic diagram of the heat sink of FIG. 2. Referring to FIG. 1, FIG. 2, and FIG. 3 at the same time, the thermal module 100 of this embodiment includes a heat sink 200.

The heat sink 200 is adapted for receiving or discharging an air flow, in which the heat sink 200 includes a body 210 and multiple heat sink fins 220. The body 210 includes a fixed plate 212 and multiple partition plates 214. The fixed plate 212 has a first surface 212a, a second surface 212b, and a third surface 212c. The first surface 212a is opposite to the second surface 212b, and the third surface 212c is connected to the first surface 212a and the second surface 212b. The heat source H is disposed closer to the first surface 212a of the fixed plate 212 than to the second surface 212b of the fixed plate 212. In one embodiment, the heat source H directly contacts the first surface 212a of the fixed plate 212. In other words, the first surface 212a is the heat-receiving surface of the heat source H.

Based on the above, the first surface 212a and the second surface 212b of this embodiment are parallel to the first direction D1. Specifically, the first surface 212a and the second surface 212b of the fixed plate 212 are parallel to the plane formed by the first direction D1 and the third direction D3 and have a common normal direction N1, and the normal direction N1 and the third direction D3 are perpendicular to the first direction D1.

The end surface 214a of each of the above-mentioned partition plates 214 is connected to the second surface 212b of the fixed plate 212, and the partition plates 214 are spaced apart from each other in a manner parallel to the second direction D2. Specifically, the partition plates 214 are arranged at intervals along the first direction D1. Each partition plate 214 has another end surface (not marked) opposite to the end surface 214a, and the surface between the two end surfaces is parallel to the plane formed by the third direction D3 and the second direction D2. The second direction D2 is perpendicular to the first direction D1 and the third direction D3. In other words, the normal direction N2 of the partition plate 214 is parallel to the first direction D1. In more detail, the normal direction N2 of the surface between two opposite end surfaces of the partition plate 214 is parallel to the first direction D1.

In the heat sink 200 of this embodiment, the number of partition plates 214 is six, and a space S is formed between any two adjacent partition plates 214 and the second surface 212b of the fixed plate 212. In other words, the arrangement of multiple partition plates 214 causes the heat sink 200 to have multiple spaces S, and each space S is provided with a corresponding heat sink fin 220. Although this embodiment illustrates that the number of partition plates 214 is six, it is not limited thereto. The heat sink 200 may have multiple spaces S when the number of partition plates 214 is three or above.

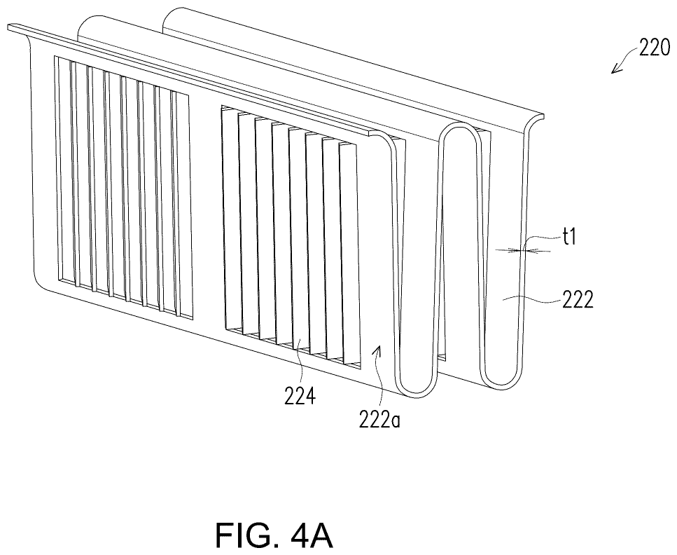

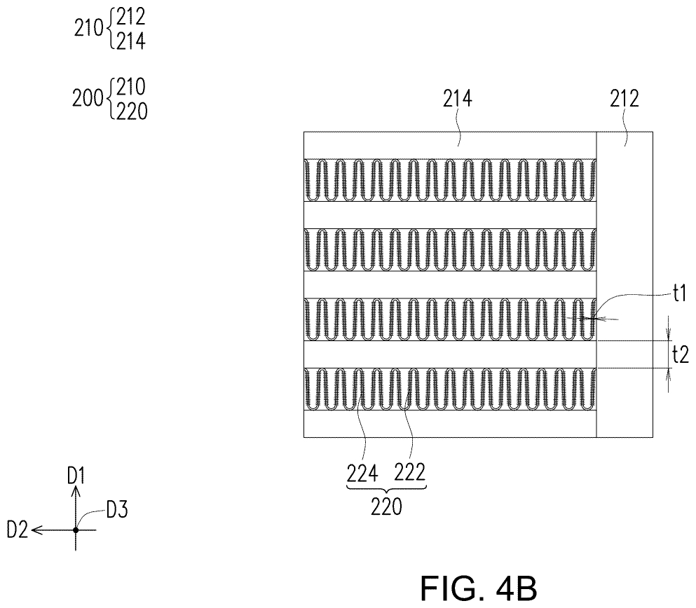

FIG. 4A is a three-dimensional schematic diagram of the heat sink fin 220, and FIG. 4B is a cross-sectional schematic diagram of the heat sink 200. Referring to FIG. 3, FIG. 4A, and FIG. 4B at the same time, the heat sink fin 220 of this embodiment has a corrugated structure, in which the orthographic projection of the corrugated structure on the plane formed by the first direction D1 and the second direction D2 is corrugated. The corrugated structure has a plurality of segments 222, and the orthographic projection of any two adjacent segments 222 on the plane is U-shaped. In other embodiments not shown, the orthographic projection of any two adjacent segments 222 of the corrugated structure on this plane may also be V-shaped.

In one embodiment, the heat sink fin 220 is flexible, so the heat sink fin 220 may deform after being stressed. Due to the flexible nature of the heat sink fin 220, the angle and distance between the adjacent segments 222 of the heat sink fin 220 may be adjusted.

In one embodiment, the thickness t1 of each segment 222 is less than 0.1 mm, and the ratio of the thickness t1 of the segment 222 to the thickness t2 of the partition plate 214 is less than 0.5. Specifically, the thickness t1 of each segment 222 refers to the width of the segment 222 in the plane formed by the first direction D1 and the second direction D2 (as shown in FIG. 4A and FIG. 4B); the thickness t2 of the partition plate 214 refers to the length of each partition plate 214 in the first direction D1 in the plane formed by the first direction D1 and the second direction D2. With such settings, the partition plates 214 may provide sufficient supporting force to support the heat sink fins 220, and the heat transferred to the partition plates 214 may be dissipated through the heat sink fins 220 more quickly.

In addition, a fractured structure 224 is disposed on the surface 222a of each segment 222 extending along the third direction D3, in which the normal direction N3 of the third surface 212c of the fixed plate 212 is parallel to the third direction D3. In this embodiment, the fractured structure 224 is a louver structure and is inclined relative to the surface 222a of each segment 222.

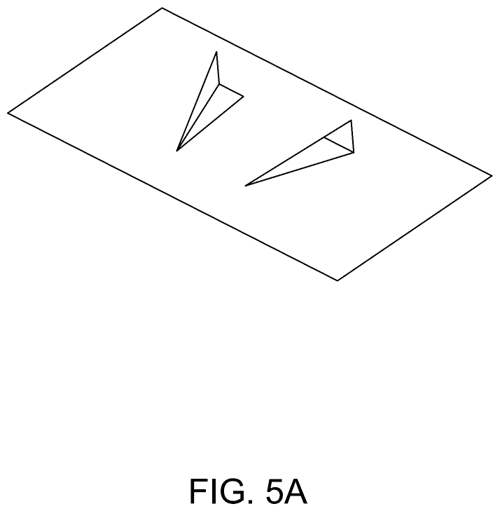

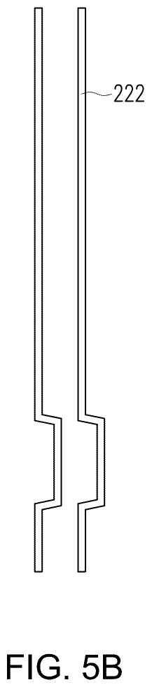

As shown in FIG. 4A, the fractured structure of this embodiment is rectangular, that is, the fractured inclined shape of the fractured structure on the surface 222a is rectangular. However, in other embodiments, the fractured structure may also be other shapes or other structures. FIG. 5A is a schematic diagram of a triangular fractured structure. FIG. 5B is a schematic diagram of the fractured structure being a concave-convex structure. As shown in FIG. 5A, the fractured structure may also be formed into a triangle, that is, it is an embodiment in which the fractured inclined shape of the fractured structure on the surface 222a is triangular. As shown in FIG. 5B, the fractured structure may also be a concave-convex structure formed on the surface of the segment 222, that is, the fractured openings in the structure are formed by protrusions or depressions.

From the above, it may be seen that the shape of the fractured structure may be changed according to requirements, as long as it may achieve the purpose of disturbing the air flow to improve the heat dissipation effect, and is not limited to the examples listed.

In one embodiment, the thermal module 100 includes a fan 300. The fan 300 is disposed close to the heat sink 200 so that the heat sink 200 may receive the air flow generated by the fan 300, and the fan 300 faces the air guide surface FI of the heat sink 200. The third surface 212c of the fixed plate 212 and the side surface 214b connected to the end surfaces 214a of the partition plates 214 form the air guide surface FI. In this embodiment, the air flow generated by the fan 300 may enter the heat sink 200 through the air guide surface FI along the third direction D3. The air flow generated by the fan 300, for example, passes between any two adjacent segments 222 of the heat sink fin 220, and the fractured structures 224 on each segment 222 are configured to disrupt the air flow. In another embodiment, the air flow generated by the fan 300 may pass through the heat sink 200 in a direction opposite to the third direction D3 and then discharge from the air guide surface FT. In other embodiments, the fan may be disposed at the far end of the heat sink 200 and guide the air flow generated by the fan to the air guide surface FT of the heat sink 200 through a guiding element, such as an air duct, so that the air flows into the heat sink 200 through the air guide surface FT or the air flows through the heat sink 200 and then discharges from the air guide surface FT.

Incidentally, the fan 300 in this embodiment is optionally employed. Compared with the situation where the fan 300 is not used in the thermal module 100, in this embodiment, the thermal module 100 is used in conjunction with the heat sink 200 and the fan 300, and the air flow generated by the fan 300 may be used to perform force convection on the heat sink 200, effectively enhancing the heat dissipation effect.

Referring to FIG. 2 and FIG. 3 at the same time, when the thermal module 100 is applied to the projector 10, the heat source H disposed close to the first surface 212a of the fixed plate 212 of the body 210 of the heat sink 200 generates heat due to operation. This heat is transferred to the first surface 212a of the fixed plate 212, passes through the fixed plate 212 to the second surface 212b, and is then transferred to the heat sink fins 220 disposed in the spaces S via the second surface 212b for heat dissipation. At the same time, a part of the heat is also transferred from the second surface 212b of the fixed plate 212 to the partition plates 214 through the end surfaces 214a, and is transferred and dissipated by the partition plates 214.

In this embodiment, when the fan 300 disposed facing the air guide surface FI operates, the air flow generated by the fan 300 passes through the air guide surface FI and enters the heat sink 200 along the third direction D3. Due to the placement position of the air guide surface FI, the air flow generated by the fan 300 may effectively pass through the surface 222a of each segment 222 of the heat sink fins 220 to take away the heat on the heat sink fins 220.

Incidentally, the fractured structure 224 disposed on the segment 222 of the heat sink fin 220 increases the overall heat dissipation effect of the heat sink 200. In detail, the fractured structure 224 disposed on the segment 222 is inclined relative to the surface 222a of the segment 222, thereby causing disturbance to the air flow flowing through the segments 222 of the heat sink fins 220 along the third direction D3, thereby increasing the thermal convection effect. Therefore the overall heat dissipation effect of the thermal module 100 may be further effectively improved.

In addition, the overall heat dissipation effect of the heat sink 200 may be changed by controlling the cross-sectional area of the air flow through the heat sink 200, the surface areas of the heat sink fins, the heat flux areas of the heat sink fins, and other factors.

Incidentally, in this embodiment, the fixed plate 212 and the partition plates 214 have the same length d1 in the third direction D3, so that the body 210 of the heat sink 200 also has the length d1 in the third direction D3. The length d1 of the body 210 in the third direction D3 is greater than the length d2 of the heat sink fin 220 in the third direction D3; that is, in the third direction D3, the length d2 of the heat sink fin 220 is less than the length d1 of the partition plate 214 (i.e., the length d1 of the body 210). Therefore, the placement position of the heat sink fin 220 may be relatively close to the fan 300 (or the air guide surface FI) in the body 210, relatively far away from the fan 300 (or the air guide surface FI), or centrally positioned (as shown in FIG. 2 and FIG. 3), which is determined according to requirements. In other words, the cross section SF may overlap with the air guide surface FI, or the cross section SF may be separated from the air guide surface FI by a certain distance. The cross section SF is a plane of the heat sink 200 cut along the first direction D1 and the second direction D2, and the cross section SF corresponds to the placement position of the edge of the heat sink fin 220 in the third direction in the heat sink 200.

In addition, considering the overall heat dissipation effect, in one embodiment, the placement position of the heat sink fin 220 corresponds to the placement position of the heat source H; that is, the orthographic projection range of the heat sink fin 220 on the fixed plate 212 at least partially overlaps the orthographic projection range of the heat source H on the fixed plate 212. Through such a placement, it may be ensured that the placement position of the heat sink fin 220 corresponds to the placement position of the heat source H, so that the heat sink 200 has a good heat dissipation effect.

Based on the above, in the cross section SF of the heat sink 200 of this embodiment, the area ratio that may allow the passage of air flow is between 60% and 70%.

Specifically, the calculation method of the area ratio that may allow the passage of air flow is as follows:

$$\frac{HSFS \times ( HSFN - 1 ) \times ( HSFH - LFN \times LFT )}{HSW \times HSFH} ,$$

HSFS is the spacing distance between two adjacent partition plates 214 in the first direction D1, HSFN is the number of partition plates 214, HSFH is the length of the partition plate 214 in the second direction D2, LFN is the number of segments 222 of each heat sink fin 220 (as shown in FIG. 4A, there are four segments 222), LFT is the thickness of each segment 222 (such as thickness t1 shown in FIG. 4A), HSW is the length of the heat sink 200 in the first direction D1.

In addition, the heat flux coefficient of the heat sink 200 in the cross section SF is between 0.3 and 0.4. Specifically, after the heat from the heat source H is transferred to the second surface 212b via the first surface 212a of the fixed plate 212, the heat is transferred from the second surface 212b to the heat sink fins 220 through the end surfaces 214a of the partition plates 214 for heat dissipation. This heat flux coefficient is the ability for the heat sink 200 to dissipate heat in the cross section SF after the heat from the heat source H is transferred to the heat sink fins 220 through the end surfaces 214a of the partition plate 214.

Specifically, the heat flux coefficient formula is:

$$\frac{HSL \times HSFT \times HSFN}{HSW \times HSFH} ,$$

HSL is the length of the heat sink 200 in the third direction D3 (which may be regarded as the length d1 in FIG. 2), HSFT is the thickness of the partition plate 214 (such as thickness t2 shown in FIG. 4B), HSFN is the number of partition plates 214, HSW is the length of the heat sink 200 in the first direction D1, HSFH is the length of the partition plate 214 in the second direction D2.

Table 1 shows a comparison of the overall volume and heat dissipation effect of a conventional heat sink and the heat sink 200 of this embodiment.

| | | Conventional | | Stacked fin | | |
|---|---|---|---|---|---|---|
| | | heat sink | | heat sink | | Heat sink |
| | | reduced in | | reduced in | | of this |
| | | volume and | | volume and | | embodiment + |
| | | temperature | | temperature | | heat sink |
| | | is allowed to | Stacked | is allowed | Conventional | fin with a |
| | Conventional | increase by | fin heat | to increase | heat sink + | fractured |
| | heat sink | 0.4° C. | sink | by 0.4° C. | metal foam | structure |
| Temperature | 47.1 | 47.5 | 47.5 | 47.9 | 50.9 | 47.4 |
| (° C.) | | | | | | |
| Flow | 3.5 | 3.6 | 3.5 | 3.4 | 3 | 3.4 |
| rate(CFM) | | | | | | |
| Length of | 40 | 40 | 40 | 40 | 40 | 40 |
| heat sink in | | | | | | |
| the first | | | | | | |
| direction | | | | | | |
| (mm) | | | | | | |
| Length of | 110 | 90 | 90 | 70 | 55 | 47 |
| heat sink in | | | | | | |
| the third | | | | | | |
| direction | | | | | | |
| (mm) | | | | | | |
| Length of | 11 | 11 | 13 | 13 | 6.4 | 6.4 |
| fixed plate | | | | | | |
| in the | | | | | | |
| second | | | | | | |
| direction | | | | | | |
| (mm) | | | | | | |
| length of | 40 | 40 | 38 | 38 | 44.6 | 44.6 |
| partition | | | | | | |
| plate in the | | | | | | |
| second | | | | | | |
| direction | | | | | | |
| (mm) | | | | | | |
| length of | 1 | 1 | 0.3 | 0.3 | 1 | 2.2 |
| partition | | | | | | |
| plate in the | | | | | | |
| first | | | | | | |
| direction | | | | | | |
| (mm) | | | | | | |
| Distance of | 3.3 | 3.3 | 2.0 | 1.7 | 3.9 | 7.6 |
| partition | | | | | | |
| plate in the | | | | | | |
| first | | | | | | |
| direction | | | | | | |
| (mm) | | | | | | |
| Passage of | 67.5% | 67.5% | 81.3% | 94.3% | NA | 65.5% |
| air flow area | | | | | | |
| ratio | | | | | | |
| Heat flux | 0.89 | 0.73 | 0.37 | 0.35 | 0.34 | 0.35 |
| coefficient | | | | | | |

As may be seen from Table 1, the heat sink 200 of this embodiment uses corrugated heat sink fins 220 in conjunction with a fractured structure 224. Compared to the conventional heat sink combined with different heat dissipation methods (stacked fins or metal foam), the overall volume of the heat sink 200 in this embodiment is reduced by more than 50%, thus significantly reducing the overall volume of the heat sink 200.

In summary, the embodiments of the present disclosure have at least one of the following advantages or effects.

In the thermal module and projector according to the embodiment of the disclosure, the heat sink uses a corrugated structure heat sink fin and a fractured structure, which not only increases the heat conduction area, but also improves the heat flow effect through the placement of the fractured structure, thus improving the overall heat dissipation effect of the heat sink.

In addition, the position of the heat sink and the air guide surface is placed in such a way that the air flow generated by the fan may pass through each segment of the heat sink fins disposed in the body of the heat sink.

The thermal module of the disclosure may provide good heat dissipation effect on the premise that it is small and light. Therefore, the projector using this thermal module is also thin and light.

However, the above are only preferred embodiments of the disclosure and are not intended to limit the scope of the disclosure; that is, all simple and equivalent changes and modifications made according to the claims and the contents of the disclosure are still within the scope of the disclosure. In addition, any of the embodiments or the claims of the disclosure are not required to achieve all of the objects or advantages or features disclosed herein. In addition, the abstract and title are provided to assist in the search of patent documents and are not intended to limit the scope of the disclosure. In addition, the terms “first,” “second” and the like mentioned in the specification or the claims are used only to name the elements or to distinguish different embodiments or scopes and are not intended to limit the upper or lower limit of the number of the elements.

What is claimed is:

1. A thermal module, adapted for dissipating heat from a heat source, comprising:
a heat sink, adapted for receiving or discharging air flow, comprising a body and a plurality of heat sink fins, wherein:
the body comprises a fixed plate and a plurality of partition plates, the fixed plate has a first surface, a second surface, and a third surface, the first surface is opposite to the second surface, the third surface is connected to the first surface and the second surface, the heat source is adapted to be disposed closer to the first surface of the fixed plate than to the second surface of the fixed plate, the second surface of the fixed plate is parallel to a first direction, a number of the plurality of partition plates is more than three and the plurality of partition plates are respectively parallel to a second direction and connected to the second surface of the fixed plate by an end surface, the first direction is perpendicular to the second direction, a plurality of spaces are formed between the plurality of partition plates and the second surface of the fixed plate; and
the plurality of heat sink fins are respectively disposed in the plurality of spaces, each of the plurality of heat sink fins has a corrugated structure, an orthographic projection of the corrugated structure on a plane formed by the first direction and the second direction is corrugated, the corrugated structure has a plurality of segments, each of the plurality of segments is provided with a fractured structure on a surface extending in a third direction, the third direction is perpendicular to the first direction and the second direction,
wherein, the third surface of the fixed plate and a side surface connected to the end surfaces of the plurality of partition plates form an air guide surface, and the heat sink receives or discharges the air flow through the air guide surface.

2. The thermal module according to claim 1, wherein in the corrugated structure, an orthographic projection of any two adjacent segments on the plane is V-shaped or U-shaped.

3. The thermal module according to claim 1, wherein a thickness of each of the plurality of segments of the corrugated structure is less than 0.1 mm.

4. The thermal module according to claim 1, wherein a ratio of a thickness of each of the plurality of segments of the corrugated structure to a thickness of each of the plurality of partition plates is less than 0.5.

5. The thermal module according to claim 1, wherein in a cross section of the heat sink, an area ratio that allows passage of the air flow is between 60% and 70%, wherein the cross section is a plane of the heat sink cut along the first direction and the second direction.

6. The thermal module according to claim 1, wherein a heat flux coefficient of the heat sink in a cross section is between 0.3 and 0.4, wherein the cross section is a plane of the heat sink cut along the first direction and the second direction.

7. The thermal module according to claim 1, wherein in the third direction, a length of one of the plurality of heat sink fins is less than a length of one of the plurality of partition plates.

8. The thermal module according to claim 1, wherein an orthographic projection range of one of the plurality of heat sink fins on the fixed plate at least partially overlaps an orthographic projection range of the heat source on the fixed plate.

9. The thermal module according to claim 1, wherein the fractured structure is a louver structure, and the louver structure is inclined relative to the surface of one of the plurality of segments.

10. The thermal module according to claim 1, further comprising:
a fan, disposed close to the heat sink, and facing the air guide surface of the heat sink, wherein the air flow generated by the fan is adapted for entering the heat sink along the third direction or causes the air flow to pass through the heat sink in a direction opposite to the third direction and then discharge from the air guide surface.

11. A projector, comprising:
a lighting module, configured to provide an illumination beam;
a light valve module, disposed on a transmission path of the illumination beam to convert the illumination beam into an image beam;
a lens module, disposed on a transmission path of the image beam to project the image beam; and
a thermal module, configured to dissipate heat from a heat source, wherein the heat source comprises at least one of the lighting module and the light valve module, the thermal module comprises:
a heat sink, adapted for receiving or discharging air flow, the heat sink comprising a body and a plurality of heat sink fins, wherein the body comprises a fixed plate and a plurality of partition plates, the fixed plate has a first surface, a second surface, and a third surface, the first surface is opposite to the second surface, the third surface is connected to the first surface and the second surface, the heat source is disposed closer to the first surface of the fixed plate than to the second surface of the fixed plate, the second surface of the fixed plate is parallel to a first direction, a number of the plurality of partition plates is more than three and the plurality of partition plates are respectively parallel to a second direction and connected to the second surface of the fixed plate by an end surface, the first direction is perpendicular to the second direction, a plurality of spaces are formed between the plurality of partition plates and the second surface of the fixed plate; and
the plurality of heat sink fins are respectively disposed in the plurality of spaces, each of the plurality of heat sink fins has a corrugated structure, an orthographic projection of the corrugated structure on a plane formed by the first direction and the second direction is corrugated, the corrugated structure has a plurality of segments, each of the plurality of segments is provided with a fractured structure on a surface extending in a third direction, the third direction is perpendicular to the first direction and the second direction,
wherein, the third surface of the fixed plate and a side surface connected to the end surfaces of the plurality of partition plates form an air guide surface, and the heat sink receives or discharges the air flow through the air guide surface.

12. The projector according to claim 11, an orthographic projection of any two adjacent segments on the plane is V-shaped or U-shaped.

13. The projector according to claim 11, wherein a thickness of each of the plurality of segments of the corrugated structure is less than 0.1 mm.

14. The projector according to claim 11, wherein a ratio of a thickness of each of the plurality of segments of the corrugated structure to a thickness of each of the plurality of partition plates is less than 0.5.

15. The projector according to claim 11, wherein in a cross section of the heat sink, an area ratio that allows passage of the air flow is between 60% and 70%, wherein the cross section is a plane of the heat sink cut along the first direction and the second direction.

16. The projector according to claim 11, wherein a heat flux coefficient of the heat sink in a cross section is between 0.3 and 0.4, wherein the cross section is a plane of the heat sink cut along the first direction and the second direction.

17. The projector according to claim 11, wherein in the third direction, a length of one of the plurality of heat sink fins is less than a length of one of the plurality of partition plates.

18. The projector according to claim 11, wherein an orthographic projection range of one of the plurality of heat sink fins on the fixed plate at least partially overlaps an orthographic projection range of the heat source on the fixed plate.

19. The projector according to claim 11, wherein the fractured structure is a louver structure, and the louver structure is inclined relative to the surface of one of the plurality of segments.

20. The projector according to claim 11, further comprising:
a fan, disposed close to the heat sink, and facing the air guide surface of the heat sink, wherein the air flow generated by the fan is adapted for entering the heat sink along the third direction or adapted for passing through the heat sink in a direction opposite to the third direction and then discharging from the air guide surface.
